(19) United States
(12) Patent Application Publication
(10) Pub. No.: US 2022/0077420 A1
(43) Pub. Date: Mar. 10, 2022

(54) REFLECTIVE ELECTRODE AND DISPLAY DEVICE HAVING THE SAME

(71) Applicant: Samsung Display Co., Ltd., Yongin-si (KR)

(72) Inventors: Gyungmin Baek, Yongin-si (KR); Hyunah Sung, Suwon-si (KR); Sukyoung Yang, Hwaseong-si (KR); Dokeun Song, Yongin-si (KR); Hyuneok Shin, Gwacheon-si (KR)

(21) Appl. No.: 17/445,462

(22) Filed: Aug. 19, 2021

(30) Foreign Application Priority Data
Sep. 9, 2020 (KR) 10-2020-0115540

(51) Int. Cl. H01L 51/52; H01L 27/32

(52) U.S. Cl. CPC H01L 51/5218; H01L 2251/308; H01L 27/3248; H01L 51/5234

(57) ABSTRACT

A reflective electrode having high heat resistance, which may include a reflective layer including aluminum (Al), iron (Fe), and vanadium (V), is disclosed. A content of the iron in the reflective layer may be 0.5 atomic % or less, based on the total number of atoms of the reflective layer.

### CROSS-REFERENCE TO RELATED APPLICATION(S)

This application claims priority to and the benefit of Korean Patent Application No. 10-2020-0115540, filed on Sep. 9, 2020 in the Korean Intellectual Property Office (KIPO), the entire content of which is hereby incorporated by reference in its entirety.

### FIELD

Embodiments of the present disclosure relate to a reflective electrode, and, for example, to a reflective electrode, and the display device having the same.

### BACKGROUND

A display device may include a plurality of pixels. Each of the plurality of pixels may include a pixel electrode. In addition, each of the plurality of pixels may include a light emitting layer electrically coupled to the pixel electrode. The light emitting layer may receive an electrical signal through the pixel electrode and may emit light having a luminance corresponding to the intensity of the transmitted electrical signal. The display device may display an image by combining light emitted from a plurality of light emitting layers.

When light emitted from the light emitting layer is absorbed into the pixel, a luminance of an image displayed by the display device may be lowered, and display efficiency of the display device may be lowered. To solve this problem, a reflective electrode may be used as the pixel electrode. The reflective electrode may reflect light emitted from the light emitting layer so that the light is not absorbed into the pixel.

### SUMMARY

Embodiments of the present disclosure provide a reflective electrode having a relatively high reflectance and a relatively high thermal resistance.

One or more embodiments provide a display device having high display efficiency.

According to embodiments of the present disclosure, there is provided a reflective electrode including a reflective layer including aluminum (Al), iron (Fe), and vanadium (V), wherein a content of the iron contained in the reflective layer is 0.5 atomic % or less, based on the total number of atoms of the reflective layer.

In one or more embodiments, a sum of a content of the iron in the reflective layer and a content of the vanadium in the reflective layer may be 0.5 atomic % or less, based on the total number of atoms of the reflective layer.

In one or more embodiments, a content of the aluminum in the reflective layer may be 99.5 atomic % or more, based on the total number of atoms of the reflective layer.

In one or more embodiments, the content of the iron in the reflective layer may be greater than the content of the vanadium in the reflective layer.

In one or more embodiments, a ratio of the content of the iron in the reflective layer to the content of the vanadium in the reflective layer may be 10:1.

In one or more embodiments, a thickness of the reflective layer may be 700 angstroms or more.

In one or more embodiments, the reflective electrode may further comprise a conductive oxide layer on a first surface of the reflective layer.

In one or more embodiments, the reflective layer may further include a barrier layer on a second surface of the reflective layer opposite to the first surface.

In one or more embodiments, the barrier layer may include indium tin oxide (ITO), titanium (Ti), and/or titanium nitride (TiN).

According to embodiments of the present disclosure, there is provided a display device including a substrate, a transistor on the substrate and a reflective electrode electrically coupled to the transistor and on the transistor, wherein the reflective electrode includes a reflective layer including aluminum, iron, and vanadium, and wherein a sum of a content of the iron in the reflective layer and a content of the vanadium in the reflective layer is 0.5 atomic % or less, based on the total number of atoms of the reflective layer.

In one or more embodiments, a content of the aluminum in the reflective layer may be 99.5 atomic % or more, based on the total number of atoms of the reflective layer.

In one or more embodiments, a ratio of the content of the iron in the reflective layer to the content of the vanadium in the reflective layer is 10:1.

In one or more embodiments, the reflective electrode may further include a conductive oxide layer on a lower surface of the reflective layer.

In one or more embodiments, the reflective electrode may further include a barrier layer on an upper surface of the reflective layer.

In one or more embodiments, the barrier layer may include indium tin oxide (ITO), titanium (Ti), and/or titanium nitride (TiN).

In one or more embodiments, the display device may further include a light emitting layer on the reflective electrode and a transparent electrode on the light emitting layer.

In one or more embodiments, the reflective electrode may be an anode, and the transparent electrode may be a cathode.

In one or more embodiments, the display device may further include a partition wall between the reflective electrode and the transistor and including a partition opening and the reflective electrode may cover a side surface of the partition wall.

In one or more embodiments, the display device may further include a light emitting layer on the partition opening of the partition wall.

In one or more embodiments, the display device may further include a first transparent electrode and a second transparent electrode on the reflective electrode and the first transparent electrode and the second transparent electrode are electrically coupled to the light emitting layer.

As described above, the reflective electrode may include the reflective layer, and the reflective layer may include aluminum, iron, and vanadium. Accordingly, a reflectance of the reflective electrode may be greater than that of pure aluminum, and a heat resistance of the reflective electrode may be greater than that of pure aluminum.

As described above, the display device may include the reflective electrode, and the reflective electrode may include the reflective layer. The reflective layer may include aluminum, iron, and vanadium. Accordingly, a display efficiency of the display device including the reflective electrode may be improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to embodiments.

FIG. 2 is a cross-sectional view illustrating a pixel according to embodiments.

FIG. 3 is a cross-sectional view illustrating a pixel according to embodiments.

FIG. 4 is an enlarged cross-sectional view of 2A of FIG. 2.

FIG. 5A is a cross-sectional view illustrating a process of etching a reflective layer.

FIG. 5B is a cross-sectional view illustrating a process of etching a reflective layer.

FIG. 5C is a cross-sectional view illustrating a process of etching a reflective layer.

FIG. 5D is a cross-sectional view illustrating a process of etching a reflective layer.

FIG. 5E is a cross-sectional view illustrating a process of etching a reflective layer.

FIG. 6A is an image showing an exposed portion of FIG. 5E.

FIG. 6B is an image showing an exposed portion of FIG. 5E.

FIG. 6C is an image showing an exposed portion of FIG. 5E.

FIG. 7 is a series of images showing a surface of a reflective layer.

FIG. 8 is a graph showing relative reflectance according to a composition of a reflective layer.

FIG. 9 is a graph showing resistance according to a composition of a reflective layer.

### DETAILED DESCRIPTION

Hereinafter, embodiments of the present disclosure will be explained in detail with reference to the accompanying drawings, wherein like reference numerals refer to like elements throughout. In this regard, embodiments of the present disclosure may have different forms and should not be construed as being limited to the descriptions set forth herein. Accordingly, the embodiments are merely described below, by referring to the figures, to explain aspects of embodiments of the present description. Throughout the disclosure, the expression “at least one of a, b or c” indicates only a, only b, only c, both a and b, both a and c, both b and c, all of a, b, and c, or variations thereof.

Since the subject matter of the present disclosure may have various modifications and several embodiments, embodiments are shown in the drawings and will be described in more detail. The effects and features of embodiments of the present disclosure, and ways to achieve them will become apparent by referring to embodiments that will be described in more detail with reference to the drawings. However, the subject matter of the present disclosure is not limited to the following embodiments but may be embodied in various forms.

It will be understood that although the terms “first,” “second,” etc. may be used herein to describe various components, these components should not be limited by these terms. These components are only used to distinguish one component from another.

In the embodiments below, the singular forms include the plural forms unless the context clearly indicates otherwise.

In the present specification, it is to be understood that the terms such as “including” or “having” are intended to indicate the existence of the features or components disclosed in the specification, and are not intended to preclude the possibility that one or more other features or components may be added.

In the embodiments below, it will be understood when a portion such as a layer, an area, or an element is referred to as being “on” or “above” another portion, it can be directly on or above the other portion, or an intervening portion may also be present.

Also, in the drawings, for convenience of description, sizes of elements may be exaggerated or contracted. For example, since sizes and thicknesses of components in the drawings may be arbitrarily illustrated for convenience of explanation, the following embodiments are not limited thereto.

In the present specification, “A and/or B” refers to A, B, or A and B. In addition, in the present specification, “at least one of A and B” refers to A, B, or A and B.

In the following embodiments, the expression that a line “extending in a first direction or a second direction” includes not only a line extending in a linear form but also extending in a zigzag or curved shape in the first or second direction.

In the following embodiments, the expression “on a plane” or “in a plane” indicates that an object is viewed from above, and the expression “on a cross-section” or “in a cross-section” indicates that a cross-section of the object cut vertically is viewed from a side. In the following embodiments, the expression “overlapping” includes overlapping “on a plane” and “on a cross-section.”

Embodiments of the present disclosure will be described below in more detail with reference to the accompanying drawings. Those components that are the same or are in correspondence are referred to with the same reference numerals regardless of the figure number.

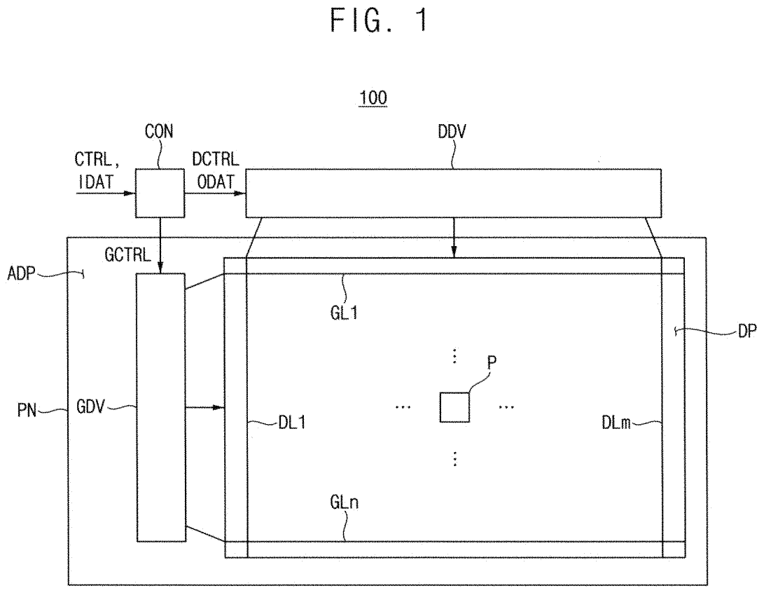

FIG. 1 is a block diagram illustrating a display device according to embodiments.

Referring to FIG. 1, a display device 100 may include a display panel PN including a display area DP and a non-display area ADP, a gate driving circuit GDV in the non-display area ADP, a data driving circuit DDV and a timing control unit CON.

The display area DP may include a plurality of gate lines GL1 to GLn, a plurality of data lines DL1 to DLm and a plurality of pixels P. The plurality of gate lines GL1 to GLn may cross and be insulated from the plurality of data lines DL1 to DLm. The plurality of pixels P may be electrically coupled to corresponding gate lines and data lines. Each of the plurality of pixels P may include a light emitting layer. In the display area DP, the light emitting layers may display an image. For example, the light emitting layers may include an organic light emitting diode (OLED), a quantum-dot organic light emitting diode (QDOLED), and/or a quantum-dot nano light emitting diode (QNED).

The timing controller CON may generate a gate control signal GCTRL, a data control signal DCTRL and an output image data ODAT. The gate control signal GCTRL, the data control signal DCTRL and the output image data ODAT may be generated based on the control signal CTRL and the input image data IDAT. For example, the control signal CTRL may include a vertical synchronization signal, a horizontal synchronization signal, an input data enable signal, a master clock signal, etc. For example, the input image data IDAT may be RGB data including red image data, green image data, and/or blue image data. In one or more embodiments, the input image data IDAT may include magenta image data, cyan image data, and/or yellow image data.

The gate driving circuit GDV may generate gate signals based on the gate control signal GCTRL from the timing controller CON. For example, the gate control signal GCTRL may include a vertical start signal, a clock signal, a gate off signal, etc.

The gate driving circuit GDV may be electrically coupled to the pixels P through the plurality of gate lines GL1 to GLn, and may output the gate signal sequentially. Each of the plurality of pixels P may be provided with a data voltage according to the control of each of the gate signals.

The data driving circuit DDV may generate the data voltage based on the data control signal DCTRL and the output image data ODAT provided from the timing controller CON. For example, the data control signal DCTRL may include an output data enable signal, a horizontal start signal and a load signal.

The data driving circuit DDV may be electrically coupled to the pixels P through the plurality of the data lines DL1 to DLm, and may generate the data voltage. Each of the pixels P may receive an electrical signal for luminance corresponding to each of the data voltage to display an image.

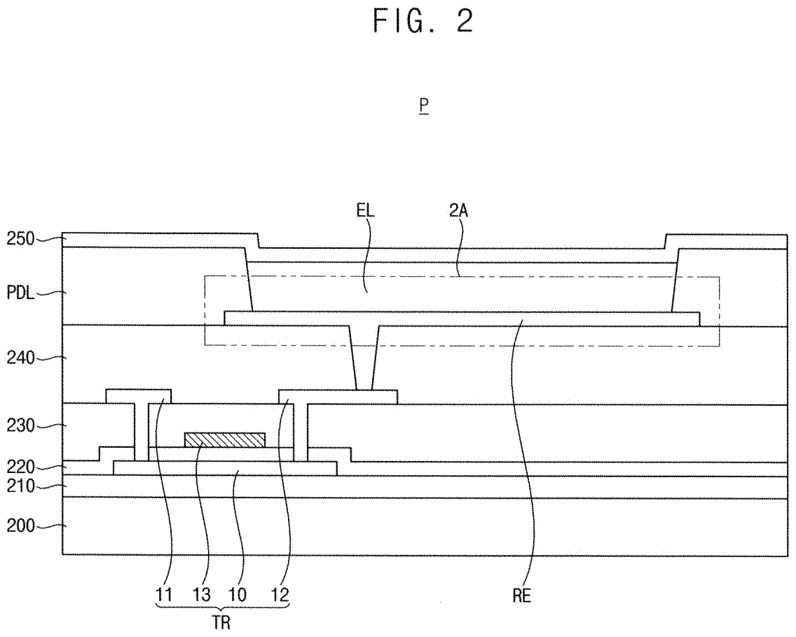

FIG. 2 is a cross-sectional view illustrating a pixel according to embodiments.

Referring to FIG. 2, a pixel P of one or more embodiments may include a substrate 200, a buffer layer 210, an active layer 10, a source electrode 11, a drain electrode 12, a gate electrode 13, a gate insulating layer 220, a first insulating layer 230, a second insulating layer 240, a reflective electrode RE, a pixel defining layer PDL, a light emitting layer EL, and a transparent electrode 250.

The substrate 200 may be an insulating substrate including glass, quartz, plastic, and/or the like. The buffer layer 210 may be on the substrate 200. The buffer layer 210 may block or reduce diffusion of impurities such as oxygen and/or moisture through the substrate 200. In addition, buffer layer 210 may include an inorganic insulating material such as silicon oxide, silicon nitride, and/or silicon oxynitride.

The active layer 10 may be on the buffer layer 110. The active layer 10 may be formed of polycrystalline silicon, amorphous silicon, oxide semiconductor, and/or the like.

The gate insulating layer 220 may be on the active layer 10. The gate insulating layer 220 may cover the active layer 10 and may be on the buffer layer 210. The gate insulating layer 220 may insulate the gate electrode 13 on the active layer 10 from the active layer 10. The gate insulating layer 220 may include an inorganic insulating material such as silicon oxide, silicon nitride, and/or silicon oxynitride.

The gate electrode 13 may be on the gate insulating layer 220. The gate electrode 13 may include a conductive material such as molybdenum (Mo) and/or copper (Cu).

The first insulating layer 230 may be on the gate electrode 13. The first insulating layer 230 may cover the gate electrode 13 and may be on the gate insulating layer 220. The first insulating layer 230 may insulate the source electrode 11 and the drain electrode 12 on the gate electrode 13 from the gate electrode 13. The first insulating layer 230 may include an inorganic insulating material such as silicon oxide, silicon nitride, and/or silicon oxynitride.

The source electrode 11 and the drain electrode 12 may be on the first insulating layer 230. The source electrode 11 and the drain electrode 12 may be electrically coupled to the active layer 10. For example, the source electrode 11 may contact one side of the active layer 10 through contact hole formed in the first insulating layer 230. For example, the drain electrode 12 may contact the other side of the active layer 10 through the contact hole formed in the first insulating layer 230 and the gate insulating layer 220. The source electrode 11 and the drain electrode 12 may include a conductive material such as aluminum (Al), titanium (Ti), copper (Cu), and/or the like. The active layer 10, the source electrode 11, the drain electrode 12 and the gate electrode 13 may constitute a transistor TR.

The second insulating layer 240 may be on the source electrode 11 and the drain electrode 12. The second insulating layer 240 may cover the source electrode 11 and the drain electrode 12 and may be on the first insulating layer 230. The second insulating layer 240 may provide a flat surface on the transistor TR. The second insulating layer 240 may include an inorganic material such as silicon oxide, silicon nitride, silicon oxynitride, and/or the like, and/or an organic material such as polyimide, and/or the like.

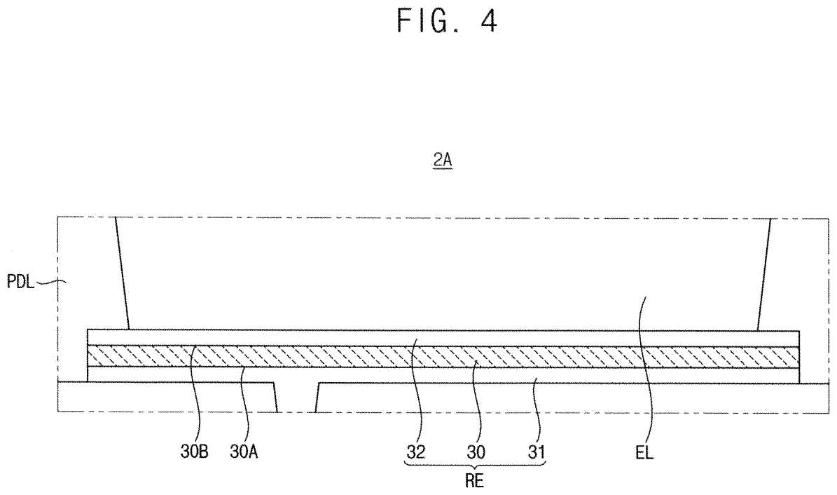

The reflective electrode RE may be on the second insulating layer 240. The reflective electrode RE may include a conductive material. For example, the reflective electrode RE may include aluminum (Al), iron (Fe), vanadium (V), and/or the like. The structure of the reflective electrode RE will be described below with reference to FIG. 4. The reflective electrode RE may be electrically coupled to the drain electrode 12. For example, the reflective electrode RE may contact one side of the drain electrode through a contact hole formed in the second insulating layer 240.

The pixel defining layer PDL may be on the reflective electrode RE. The pixel defining layer PDL may cover a portion of the reflective electrode RE and may be on the second insulating layer 240. The pixel defining layer PDL may have a pixel opening exposing at least a portion of the reflective electrode RE. For example, the pixel opening may expose a central portion of the reflective electrode RE, and the pixel defining layer PDL may cover the peripheral portion of the reflective electrode RE. The pixel defining layer PDL may include an organic insulating material such as polyimide (PI), and/or the like. The reflective electrode RE may be an anode or a cathode.

The light emitting layer EL may be on the reflective electrode RE. The light emitting layer EL may be on the reflective electrode RE exposed by the pixel opening. The light emitting layer EL may include at least one of an organic light emitting material and/or a quantum dot. The light emitting layer EL may receive an electrical signal from the transistor TR through the reflective electrode RE. The light emitting layer EL may emit light having a luminance corresponding to the intensity of the electrical signal.

In embodiments, the organic light emitting material may include a low molecular weight organic compound and/or a high molecular weight organic compound. For example, the low molecular weight organic compound may include copper phthalocyanine, diphenyl benzidine (N,N′-diphenyl benzidine), tris-(8-hydroxyquinoline)aluminum, etc. For example, the high molecular weight organic compound may include poly(3,4-ethylenedioxythiophene), polyaniline, poly-phenylenevinylene, polyfluorene, etc.

In embodiments, the quantum dot may include a core including a group II-VI compound, a group III-V compound, a group IV-VI compound, a group IV compound, a group VI compound and combinations thereof. In embodiments, the quantum dot may have a core-shell structure including a core and a shell surrounding the core. The shell may serve as a protective layer for maintaining semiconductor properties by preventing or reducing chemical modification of the core and as a charging layer for imparting electrophoretic properties to quantum dots.

The transparent electrode 250 may be on the light emitting layer EL. In embodiments, the transparent electrode 250 may also be on the pixel defining layer PDL. The transparent electrode 250 may include a conductive material such as a metal, an alloy, a transparent conductive oxide, etc. For example, the transparent electrode 250 may include aluminum (Al), platinum (Pt), silver (Ag), magnesium (Mg), gold (Au), chromium (Cr), tungsten (W), titanium (Ti), and/or the like. The transparent electrode 250 may be an anode or a cathode.

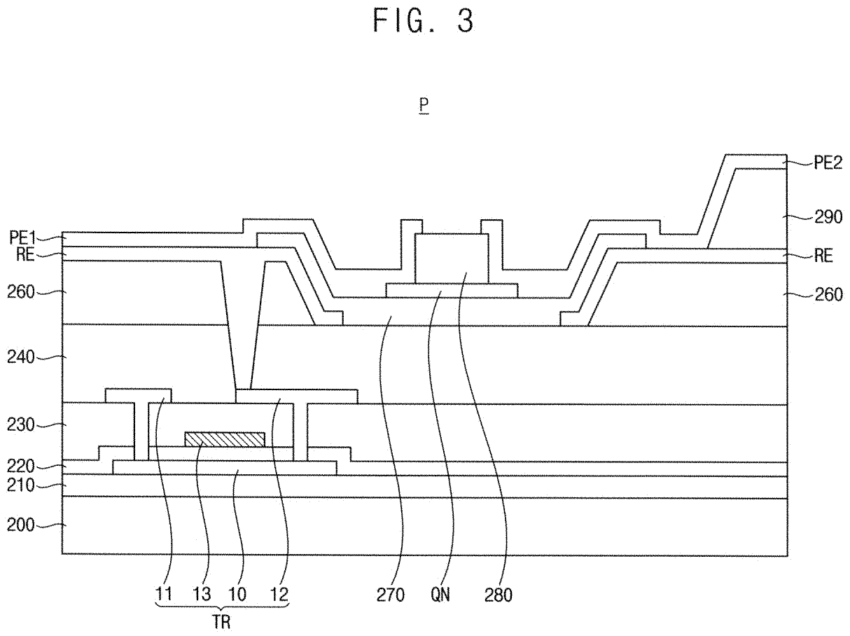

FIG. 3 is a cross-sectional view illustrating a pixel according to embodiments.

Referring to FIG. 3, a partition wall 260 may be on the second insulating layer 240. The partition wall 260 may include an inorganic insulating material and/or an organic insulating material. The partition wall 260 may include a partition wall opening exposing the second insulating layer 240.

A reflective electrode RE may be on the partition wall 260. The reflective electrode RE may cover a side surface of the partition wall 260 and may cover a portion of the surface of the second insulating layer 240 exposed by the partition wall opening. The reflective electrode RE may reflect light emitted from a light emitting layer QN.

A third insulating layer 270 may be on the second insulating layer 240. The third insulating layer 270 may cover a portion of the reflective electrode RE. The third insulating layer 270 may transmit light emitted from the light emitting layer QN.

The light emitting layer QN may be on the third insulating layer 270. The light emitting layer QN may include rods including gallium nitride (GaN). The light emitting layer QN may be electrically coupled to a first transparent electrode PE1 and a second transparent electrode PE2. Each of the rods may emit light by receiving electrical signals input through the first and second transmissive electrodes PE1 and PE2.

A fourth insulating layer 280 may be on the light emitting layer QN. The fourth insulating layer 280 may transmit light emitted from the light emitting layer QN.

The first transparent electrode PE1 and the second transparent electrode PE2 may be on the reflective electrode RE. The first transparent electrode PE1 may be electrically coupled to the transistor TR through the reflective electrode RE. For example, the reflective electrode RE may contact one side of the drain electrode 12 through a contact hole formed in the second insulating layer 240 and the partition wall 260, and the first transparent electrode PE1 may contact the reflective electrode RE. A bank 290 may be between the reflective electrode RE and the second transparent electrode PE2. The bank 290 may include an organic insulating material. The second transparent electrode PE2 may be electrically coupled to another transistor. The first transparent electrode PE1 and the second transparent electrode PE2 may cover portions of the third insulating layer 270, the light emitting layer QN and the fourth insulating layer 280.

FIG. 4 is an enlarged cross-sectional view of 2A of FIG. 2.

Referring to FIG. 4, the reflective electrode RE may be electrically coupled to the drain electrode (12 in FIG. 2) and may transmit an electric signal transmitted through the drain electrode (12 in FIG. 2) to the light emitting layer EL. In addition, the reflective electrode RE may reflect light emitted from the light emitting layer EL without or substantially without absorbing the light, thereby improving display efficiency of the display device.

The reflective electrode RE may include a reflective layer 30, a conductive oxide layer 31, and a barrier layer 32. The reflectance of reflective layer 30 may be greater than the reflectance of the conductive oxide layer 31. The reflectance of reflective layer 30 may be greater than the reflectance of the barrier layer 32. The oxide conductive layer 31 may be on the first surface 30A of the reflective layer 30. The conductive oxide layer 31 may be electrically coupled to the drain electrode (12 in FIG. 2) and transmit the electric signal transmitted through the drain electrode (12 in FIG. 2) to the reflective layer 30. The conductive oxide layer 31 may include ITO. The barrier layer 32 may be on the second surface 30B of the reflective layer 30. The barrier layer 32 may include ITO, Ti, TiN, and/or the like. An adhesion of the barrier layer 32 to the pixel defining layer PDL may be higher than an adhesion of the reflective layer 30 to the pixel defining layer PDL. Further, an adhesion of the barrier layer 32 to the light emitting layer EL may be higher than an adhesion of the reflective layer 30 to the light emitting layer EL. Accordingly, when the barrier layer 32 is on the second surface 30B of the reflective layer 30, and the pixel defining layer PDL and the light emitting layer EL are on the reflective electrode RE, the durability of the display device may be increased.

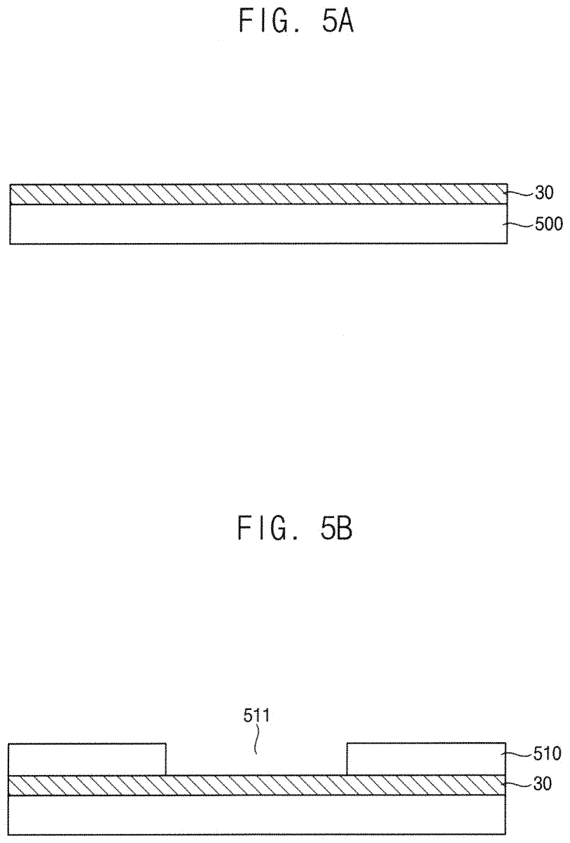

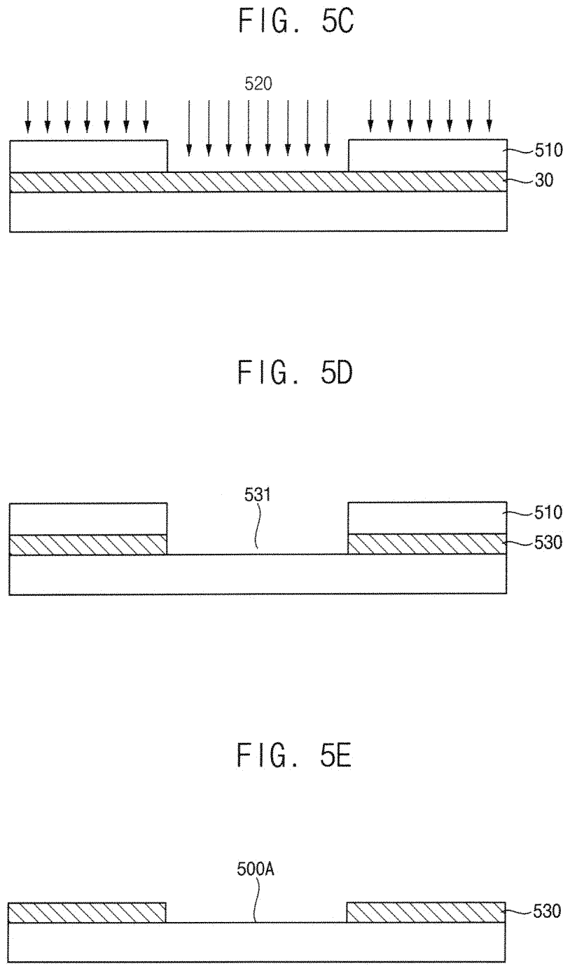

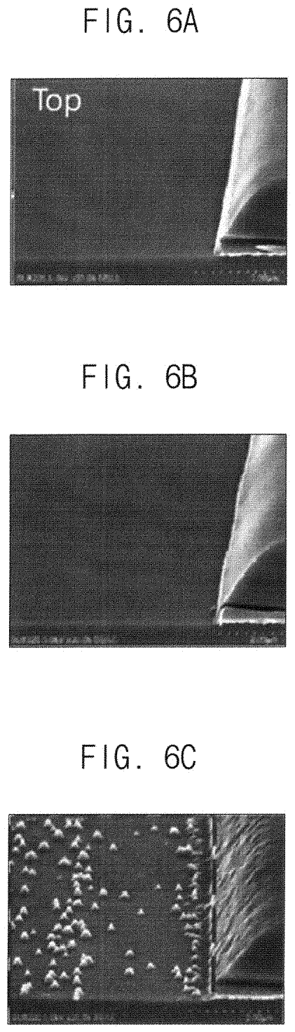

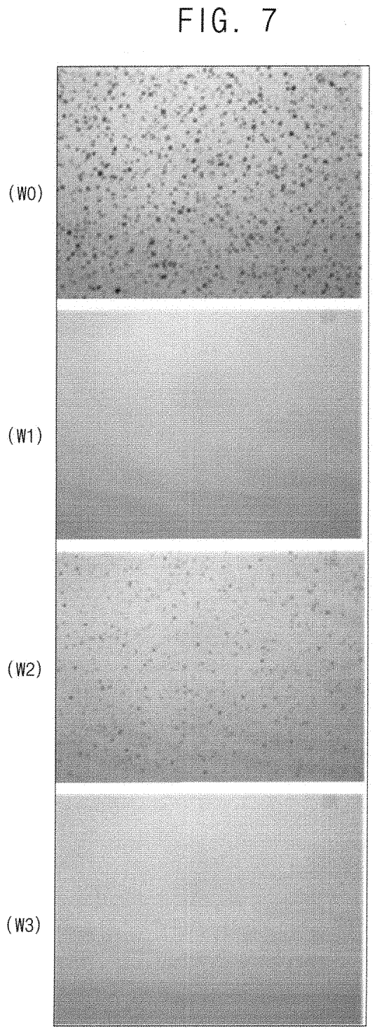

In one or more embodiments, the reflective layer 30 may be an aluminum alloy including iron, and in this case, the content of the iron included in the reflective layer 30 may be about 0.5 atomic % or less, based on the total number of atoms of the reflective layer. As used herein, the term “atomic %” may also be referred to as “atomic percent” or “at. %,” and the term “content” may refer to an “amount” or “atomic %.” The iron may reduce roughness of the surface of the reflective electrode 30. Accordingly, the reflectance of the reflective layer 30 may increase. When the iron content in the reflective layer 30 is greater than about 0.5 atomic %, based on the total number of atoms of the reflective layer, the reflective layer 30 may not be dry etched. This will be described in more detail below with reference to FIG. 5 and FIG. 6.

In one or more embodiments, the reflective layer 30 may be an aluminum alloy including iron and vanadium, and in this case, the content of the iron contained in the reflective layer 30 may be about 0.5 atomic % or less, based on the total number of atoms of the reflective layer. In the process of manufacturing the display device at a temperature of about 200° C. to about 250° C., the stress on the surface of the reflective layer 30 may be concentrated and a hillock, which is a hemispherical projection, may occur on the surface of the reflective layer 30. The vanadium may relieve stress in the reflective layer 30 so that the hillock does not occur or substantially does not occur. This will be described in more detail below with reference to FIG. 7.

In certain embodiments, the reflective layer 30 may be an aluminum alloy including iron and vanadium, and in this case, the sum of the content of the iron contained in the reflective layer 30 and the content of the vanadium contained in the reflective layer 30 may be about 0.5 atomic % or less, based on the total number of atoms of the reflective layer, and a ratio of the iron content and the vanadium content may be about 10:1. This will be described in more detail below with reference to FIG. 7 to FIG. 9.

In one or more embodiments, the thickness of the reflective layer 30 may be about 700 angstroms or more. When the thickness of the reflective layer 30 is less than about 700 angstroms, light emitted from the light emitting layer EL may pass through reflective layer 30, and the reflectance of the reflective layer 30 may be lowered. Accordingly, display efficiency of display device may decrease.

FIG. 5A to FIG. 5E are cross-sectional views illustrating a process of etching a reflective layer. FIG. 6A to FIG. 6C are images showing an exposed portion 500A of FIG. 5E.

Referring to FIG. 5A, a reflective layer 30 may be on a substrate 500. The substrate 500 may include an inorganic insulating material, an organic insulating material, and/or a conductive oxide. The reflective layer 30 may include aluminum and/or iron.

Referring to FIG. 5B, a resist pattern 510 may be on the reflective layer 30. The resist pattern 510 may include a polymer organic material. The resist pattern 510 may have a first opening 511 exposing at least a portion of the reflective layer 30.

Referring to FIG. 5C, plasma 520 may be irradiated on or to the resist pattern 510 and the reflective layer 30. The plasma may be an argon cation.

Referring to FIG. 5D, a portion of the reflective layer 30 exposed by the resist pattern 510 may be removed by the plasma 520 and a reflective pattern 530 may be formed. The reflective pattern 530 may have a second opening 531 exposing a portion of the substrate 500.

Referring to FIG. 5E, the resist pattern 510 may be removed. In this case, when the content of iron contained in the reflective layer 30 is greater than about 0.5 atomic %, based on the total number of atoms of the reflective layer, the residual amount of the reflective layer 30 in the exposed portion 500A of the substrate 500 exposed by the second opening 531 may remain.

Referring to FIG. 6A, the reflective layer 30 may include aluminum and iron, and the content of iron contained in the reflective layer 30 may be about 0.2 atomic %, based on the total number of atoms of the reflective layer. In this embodiment, after etching the reflective layer 30, the residual amount of the reflective layer 30 may not remain in the exposed portion 500A.

Referring to FIG. 6B, the reflective layer 30 may include aluminum and iron, and the content of the iron contained in the reflective layer may be about 0.4 atomic %, based on the total number of atoms of the reflective layer. In this embodiment, after etching the reflective layer 30, the residual amount of the reflective layer 30 may not remain in the exposed portion 500A.

Referring to FIG. 6C, the reflective layer 30 may include aluminum and iron, and the content of iron contained in the reflective layer 30 may be about 0.6 atomic %, based on the total number of atoms of the reflective layer. In this embodiment, after etching the reflective layer 30, the residual amount of reflective layer 30 may remain in the exposed portion 500A.

FIG. 7 includes images showing a surface of a reflective layer.

Referring to FIG. 7, the reflective layer (30 in FIG. 4) is made of a sample of 7 cm by 7 cm having a thickness of 3000 angstroms and may be heated at 250° C. for 1 hour in a furnace filled with nitrogen gas. The composition of the reflective layer 30 is shown in Table 1 below.

TABLE 1

| | W0 | W1 | W2 | W3 |
|---|---|---|---|---|
| Aluminum | 100 atomic % | 99.4 atomic % | 99.4 atomic % | 99.78 atomic % |
| Iron | 0 | 0.45 atomic % | 0.6 atomic % | 0.2 atomic % |
| Vanadium | 0 | 0.15 atomic % | 0 | 0.02 atomic % |

W0 refers to a composition composed of only aluminum, and W1 refers to a composition composed of about 99.4 atomic % aluminum, about 0.45 atomic % iron and about 0.15 atomic % vanadium. W2 refers to a composition composed of about 99.4 atomic % aluminum and about 0.6 atomic % iron, and W3 refers to a composition composed of about 99.78 atomic % aluminum, 0.2 atomic % iron and 0.02 atomic % vanadium. When the reflective layer 30 is made of pure aluminum (W0), a number of hillocks indicated by black dots in the image may occur. The number of hillocks when the reflective layer 30 has a composition of W2 may be smaller than that of the hillock when the reflective layer 30 is pure aluminum. When the reflective layer 30 has a composition of W1 or W3, hillock may not occur in the reflective layer 30. For example, when vanadium is added to the reflective layer 30 including aluminum and iron, it is possible to suppress or reduce the occurrence of hillocks.

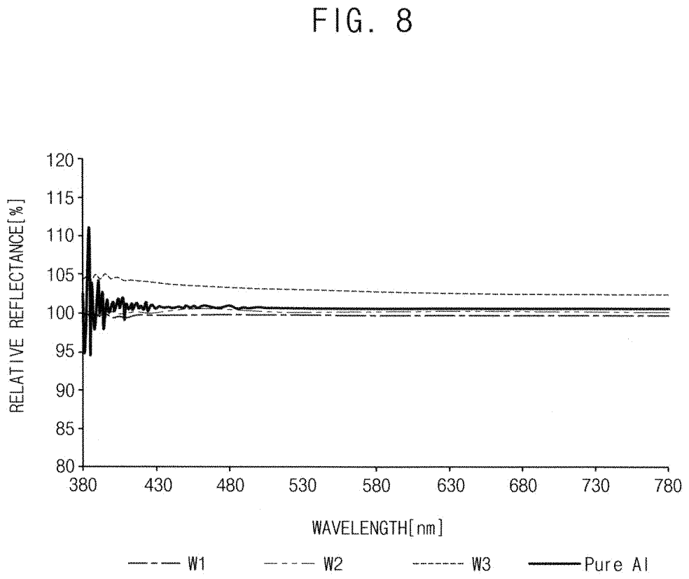

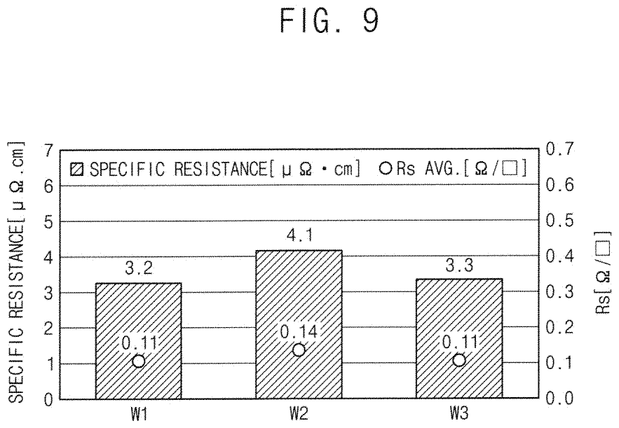

FIG. 8 is a graph showing relative reflectance according to a composition of a reflective layer. FIG. 9 is a graph showing resistance according to a composition of a reflective layer.

Referring to FIG. 8, in the graph of FIG. 8, when the reflective layer (30 in FIG. 4) is pure aluminum, the degree of reflection of light of various wavelengths from the reflective layer 30 is shown as 100%. In addition, in the graph of FIG. 8, when the composition of the reflective layer 30 is W1 to W3, the degree of reflection of various wavelengths from the reflective layer 30 is relatively shown. When the composition of the reflective layer 30 is W1, about 100% of light having a wavelength of 550 nm may be reflected, and about 100% of light having a wavelength of the visible light region may be reflected on average. When the composition of the reflection layer 30 is W2, about 100% of light having a wavelength of 550 nm may be reflected, and about 100% of light having a wavelength of the visible light region may be reflected on average. When the composition of the reflective layer 30 is W3, about 103% of light having a wavelength of 550 nm may be reflected, and about 103% of light having a wavelength of the visible light region may be reflected on average.

When the composition of the reflective layer 30 is W1, reflectance equal to or greater than that of pure aluminum may be exhibited at a wavelength in the visible light region. When the composition of the reflective layer 30 is W3, a higher reflectance than pure aluminum may be exhibited at a wavelength in the visible light region. For example, when the sum of the iron content and the vanadium content in the reflective layer 30 is less than about 0.5 atomic %, the reflectance of the reflective layer 30 may be greater than that of pure aluminum. For example, when the ratio of the content of the iron atom included in the reflective layer 30 and the content of the vanadium atom included in the reflective layer 30 is about 10:1, a higher reflectance than pure aluminum may be exhibited.

Referring to FIG. 9, the graph of FIG. 9 shows the specific resistance and sheet resistance when the reflective layer (30 in FIG. 4) is made of a sample of 7 cm by 7 cm having a thickness of approximately 3000 angstroms and heated at approximately 250° C. for 1 hour in a furnace filled with nitrogen gas. When the reflective layer 30 is pure aluminum, it may have a resistivity of about 2.8 μΩcm. When the reflective layer 30 has a composition of W1, it may have a specific resistance of about 3.2 μΩcm and a sheet resistance of about 0.11Ω/□ (also referred to as “ohms per square” or “Ω/sq”). When the reflective layer 30 has a composition of W2, it may have a specific resistance of about 4.1 μΩcm and a sheet resistance of about 0.14Ω/□. When the reflective layer 30 has a composition of W3, it may have a specific resistance of about 3.3 μΩcm and a sheet resistance of about 0.11 Ω/□.

The specific resistance when the reflective layer 30 has a composition of W2 is greater than the specific resistance when the reflective layer 30 has a composition of W1 or W3. For example, when the content of iron contained in the reflective layer 30 exceeds about 0.5 atomic %, the specific resistance may increase when a high temperature of about 250° C. is applied. Accordingly, electrical characteristic may be deteriorated, and display efficiency of the display device may be lowered. When the reflective layer 30 has a composition of W2, even when a high temperature of about 250° C. is applied, it may have a specific resistance of about 3.2 μΩcm. For example, when the content of iron contained in the reflective layer 30 is less than about 0.5 atomic %, even when a high temperature of about 250° C. is applied, a relatively low specific resistance may be obtained. When the reflective layer 30 has a composition of W3, even when a high temperature of about 250° C. is applied, it may have a specific resistance of about 3.3 μΩcm. For example, when the sum of the iron content and the vanadium content in the reflective layer 30 is about 0.5 atomic % or less, and the ratio of the iron atom content and the vanadium atom content is about 10:1, even when a high temperature of about 250° C. is applied, it may have a relatively low specific resistance.

The subject matter of the present disclosure may be applied to any reflective electrode 30. For example, the subject matter of the present disclosure may be applied to a reflective electrode of a display device included in a mobile phone, a smart phone, a wearable electronic device, a tablet computer, a television (TV), a digital TV, a 3D TV, a personal computer (PC), a home appliance, a laptop computer, a personal digital assistant (PDA), a portable multimedia player (PMP), a digital camera, a music player, a portable game console, a navigation device, etc.

The foregoing is illustrative of embodiments and is not to be construed as limiting thereof. Although a few embodiments have been described, those skilled in the art will readily appreciate that many modifications are possible in the embodiments without materially departing from the spirit and scope of the present disclosure. Accordingly, all such modifications are intended to be included within the scope of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and equivalents thereof.

What is claimed is:

1. A reflective electrode, comprising:
a reflective layer comprising aluminum (Al), iron (Fe), and vanadium (V),
wherein a content of the iron contained in the reflective layer is 0.5 atomic % or less, based on the total number of atoms of the reflective layer.

2. The reflective electrode of claim 1, wherein a sum of a content of the iron in the reflective layer and a content of the vanadium in the reflective layer is 0.5 atomic % or less, based on the total number of atoms of the reflective layer.

3. The reflective electrode of claim 2, wherein a content of the aluminum in the reflective layer is 99.5 atomic % or more, based on the total number of atoms of the reflective layer.

4. The reflective electrode of claim 2, wherein the content of the iron in the reflective layer is greater than the content of the vanadium in the reflective layer.

5. The reflective electrode of claim 4, wherein a ratio of the content of the iron in the reflective layer to the content of the vanadium in the reflective layer is 10:1.

6. The reflective electrode of claim 1, wherein a thickness of the reflective layer is 700 angstroms or more.

7. The reflective electrode of claim 1, further comprising:
a conductive oxide layer on a first surface of the reflective layer.

8. The reflective electrode of claim 7, further comprising:
a barrier layer on a second surface of the reflective layer opposite to the first surface.

9. The reflective electrode of claim 8, wherein the barrier layer comprises indium tin oxide (ITO), titanium (Ti), or titanium nitride (TiN).

10. A display device, comprising:
a substrate;
a transistor on the substrate; and
a reflective electrode electrically coupled to the transistor and on the transistor,
wherein the reflective electrode comprises a reflective layer comprising aluminum, iron, and vanadium, and
wherein a sum of a content of the iron in the reflective layer and a content of the vanadium in the reflective layer is 0.5 atomic % or less, based on the total number of atoms of the reflective layer.

11. The display device of claim 10, wherein a content of the aluminum in the reflective layer is 99.5 atomic % or more, based on the total number of atoms of the reflective layer.

12. The display device of claim 11, wherein a ratio of the content of the iron in the reflective layer to the content of the vanadium in the reflective layer is 10:1.

13. The display device of claim 10, wherein the reflective electrode further comprises a conductive oxide layer on a lower surface of the reflective layer.

14. The display device of claim 13, wherein the reflective electrode further comprises a barrier layer on an upper surface of the reflective layer.

15. The display device of claim 14, wherein the barrier layer comprises indium tin oxide (ITO), titanium (Ti), and/or titanium nitride (TiN).

16. The display device of claim 10, further comprising:
a light emitting layer on the reflective electrode; and
a transparent electrode on the light emitting layer.

17. The display device of claim 16, wherein the reflective electrode is an anode, and the transparent electrode is a cathode.

18. The display device of claim 10, further comprising:
a partition wall between the reflective electrode and the transistor and comprising a partition opening,
wherein the reflective electrode covers a side surface of the partition wall.

19. The display device of claim 18, further comprising:
a light emitting layer on the partition opening of the partition wall.

20. The display device of claim 19, further comprising:
a first transparent electrode and a second transparent electrode on the reflective electrode,
wherein the first transparent electrode and the second transparent electrode are electrically coupled to the light emitting layer.
